(19) United States
(12) Patent Application Publication
(10) Pub. No.: US 2007/0200214 A1
(43) Pub. Date: Aug. 30, 2007

(54) Board strip and method of manufacturing semiconductor package using the same

(75) Inventor: Bong-hui Lee, Yongin-si (KR)

Correspondence Address: DRINKER BIDDLE & REATH LLP;ATTN: PATENT DOCKET DEPT., 191 N. WACKER DRIVE, SUITE 3700, CHICAGO, IL, 60606, US

(73) Assignee: Samsung Techwin Co., Ltd., Changwon-city (KR)

(21) Appl. No.: 11/709,016

(22) Filed: Feb. 20, 2007

(30) Foreign Application Priority Data
Feb. 24, 2006 (KR) 10-2006-0018447

(51) Int. Cl. H01L 23/02

(52) U.S. Cl. 257/678

(57) ABSTRACT

Provided is a board strip that includes a base substrate that has at least one hole and a plurality of functional portions in which at least one semiconductor chip is packaged; a circuit layer having a circuit pattern formed on the functional portions and dummy patterns formed on non-functional portions which are formed on a surface of the base substrate respectively; a protective layer formed on the circuit layer; and at least one vacuuming hole seating unit that is formed in a portion of the non-functional portions, is disposed on a portion that contacts a vacuuming hole, and is flat without a step difference.

### CROSS-REFERENCE TO RELATED PATENT APPLICATION

This application claims the benefit of Korean Patent Application No. 10-2006-0018447, filed on Feb. 24, 2006, in the Korean Intellectual Property Office, the disclosure of which is incorporated herein in its entirety by reference.

### BACKGROUND OF THE INVENTION

1. Field of the Invention

The present invention relates to a board strip, and more particularly, to a board strip having a structure that can prevent the penetration of a protective layer into an interface between a base substrate and a vacuum stage around holes during the formation of the protective layer on a base substrate.

2. Description of the Related Art

A typical semiconductor package includes a printed circuit board (PCB) substrate and at least one circuit element (e.g., semiconductor integrated circuit (IC) chip, etc.) mounted thereon. Referring to FIGS. 1, 2, and 3, a plurality of PCB substrates 10 is often fabricated from a single board strip. The plurality of PCB substrates 10 may be configured or arranged on the board strip in one or more unit substrates 20. As shown in FIG. 1, an example board strip may include three unit substrates 20 and each unit substrate 20 may include fifteen PCB substrates 10 so that the board strip may yield forty-five substrates 10. Of course, board strips and/or substrates 10, 20 may be configured (e.g., shaped and/or sized) differently to yield fewer or additional PCB substrates 10. The unit substrates 20 are connected to each other through dummy substrates 30. After at least one semiconductor chip is mounted on each of the printed circuit substrates 10 and the resultant products are molded or encapsulated using a molding material, the printed circuit substrates 10 are separated into individual package units through a cutting process.

In this case, the unit substrate 20 and the dummy substrates 30 share a base substrate 11 (FIG. 3). The base substrate 11 is formed by stacking at least one layer of prepreg (e.g., formed of a resin material 13 such as bismaleimide triazine (BT) or FR-4) and a fibroid material 12 such as a glass fiber.

Circuit patterns 24 having a particular pattern are formed on the top and/or bottom surfaces of one or more portions of the base substrate 11 that include the unit substrate(s) 20. In addition, vias or through holes 36 that connect the circuit patterns 24 on the top and bottom surfaces may be formed, and device holes, which are used to connect the semiconductor chip to the circuit patterns 24, may be formed in the portion of the base substrate 11 included in the unit substrate 20. A portion of the base substrate 11 that includes the unit substrate(s) 20 and the circuit patterns 24 is often referred to as a “functional” portion since it is employed for fabrication of semiconductor packages.

Dummy patterns 34 having a particular pattern are formed on upper and/or lower surfaces of the base substrate 11 of the dummy substrate 30. A portion of the base substrate 11 that includes the dummy substrate 30 and the dummy patterns 34 is often referred to as a “non-functional” portion since it is typically disposed of because of its unsuitability for mounting components thereon. The dummy patterns 34 are configured so that the upper and lower surfaces of the base substrate 11 have the substantially same thermal expansion coefficient, and reinforce the strength of the board strip. In this case, the dummy patterns 34 having a rectangular shape (FIG. 2) can be disposed parallel to each other.

To protect the circuit patterns 24 from the environment, a protective layer 40 (e.g., a solder resist or a photo solder resist) is formed on the circuit patterns 24 and the dummy patterns 34. The protective layer 40 is formed by coating a protective layer material on the base substrate 11 while the base substrate 11 is attracted to a vacuum stage 50 and held thereto using a vacuum. The protective layer 40 can then be exposed and developed.

The vacuum stage 50 includes a seating surface 52 on which the base substrate 11 is seated and a plurality of vacuuming holes 54 to attract the base substrate 11 to the seating surface 52. As best shown in FIG. 1, the plurality of vacuuming holes 54 is configured so that each hole 54 of the plurality is generally aligned with the dummy substrate 30. More particularly, the unit substrate(s) 20 and the dummy substrate 30 of the board strip are configured so that the dummy substrate 30 is generally aligned with the plurality of vacuuming holes 54. A negative pressure is established inside the plurality of vacuuming holes 54 to attract a portion of the base substrate 11 where the dummy patterns 34 are located. Thus, the base substrate 11 is tightly seated or held on the seating surface 52 of the vacuum stage 50.

However, as can be appreciated, the vacuuming hole 54 has a diameter greater than a predetermined size so that the base substrate 11 can be sufficiently attracted and held to the seating surface 52. As best shown in FIGS. 2 and 3, the dummy patterns 34 are smaller than the vacuuming hole 54. As further shown, the dummy patterns 34 may not be formed on a bottom side of the substrate. Accordingly, when the vacuuming hole 54 attracts the base substrate 11, the vacuuming hole 54 is not substantially sealed by the substrate 11 or patterns 24, 34 when the substrate is being attracted to the vacuum stage 50.

As shown in FIG. 3, there is a step difference due to the thickness of the patterns 24 and 34 between a surface of the base substrate 11 where the dummy pattern 34 is formed and a surface of the base substrate 11 where the dummy pattern 34 is not formed. The step difference causes a space between the bottom surface of base substrate 11 and the vacuuming hole 54. As a result, when a vacuum is established in the vacuuming hole 54, the vacuum is also established in the space between the base substrate 11 and the seating surface 52.

In particular, in the process of coating the protective layer 40, the protective layer 40 fills the holes such as the vias or through holes 36. At this time, the protective layer 40 penetrates regions surrounding the through holes between the bottom surface of base substrate 11 and the vacuum stage 50 since the base substrate 11 does not tightly contact the vacuuming hole 54.

As a result, the surface of the base substrate 11 facing the vacuum stage 50 becomes at least partially coated with the protective layer 40. Thus, the flatness of the base substrate 11 is impaired. Furthermore, voids may be generated in the protective layer 40 (e.g., in the through hole 36), thereby reducing product reliability.

In view of the foregoing, a board strip having a structure that can prevent the penetration of a protective layer into regions surrounding the through holes between the base substrate and the vacuum stage would be an important improvement in the art.

### SUMMARY OF THE INVENTION

According to an aspect of the present invention, there is provided a board strip comprising: a base substrate including a functional portion on which at least one semiconductor chip is packaged, a non-functional portion and at least one hole; a circuit layer including a circuit pattern that is formed on at least one surface of the functional portion and a dummy pattern that is formed on at least one surface of the non-functional portion; a protective layer formed on the circuit layer; and at least one vacuuming hole seating unit formed on the non-functional portion, the at least one vacuuming hole seating unit being configured to seal at least one vacuuming hole of a vacuum stage.

The vacuuming hole seating unit may be formed of the same material as the dummy pattern.

The base substrate may be formed of a material comprising at least one of FR-4 and bismaleimide triazine (BT).

According to another aspect of the present invention, there is provided a method of manufacturing a semiconductor package comprising: providing a base substrate, for example, by a reel-to-reel process; forming circuit patterns on at least one surface of functional portions of the base substrate; forming dummy patterns on at least one surface of non-functional portions of the base substrate; forming holes in at least one of the functional and non-functional portions of the base substrate; forming a vacuuming hole seating unit on the non-functional portion of the base substrate, the at least one vacuuming hole seating unit being configured to seal at least one vacuuming hole of a vacuum stage ; seating the base substrate on the vacuum stage so that the at least one vacuuming hole of the vacuum stage is sealed by the vacuuming hole seating unit; forming a protective layer on the base substrate; and packaging a semiconductor chip on the base substrate.

### BRIEF DESCRIPTION OF THE DRAWINGS

FIG. 1 is a plan view of a conventional board strip;

FIG. 2 is an enlarged plan view of a portion indicated by A in FIG.1;

FIG. 3 is a cross-sectional view taken along line III-III of FIG. 1;

FIG. 4 is a plan view of an example board strip according to an aspect of the present invention;

FIG. 5 is an enlarged plan view of a portion indicated by B in FIG.4;

FIG. 6 is a cross-sectional view taken along line VI-VI of FIG. 4;

FIG. 7 is an enlarged plan view of a modified version of FIG. 5;

FIG. 8 is a flow chart of an example method of manufacturing a semiconductor package according to another aspect of the present invention;

FIG. 9 is a perspective view showing steps for providing a base substrate;

FIG. 10 is a cross-sectional view taken along line X-X of FIG. 9;

FIG. 11 is a cross-sectional view showing steps for forming a circuit pattern, a dummy pattern, a vacuuming hole seating unit, and a seating surface and holes in a base substrate; and

FIG. 12 is a cross-sectional view illustrating the forming of a protective layer on a base substrate;

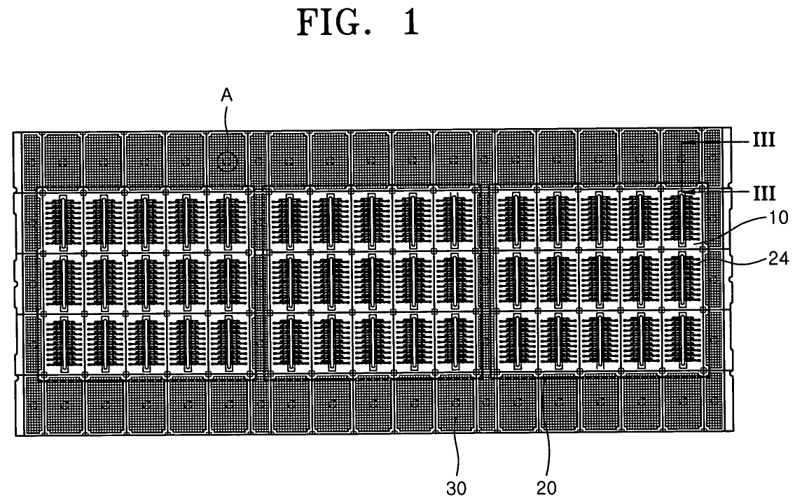

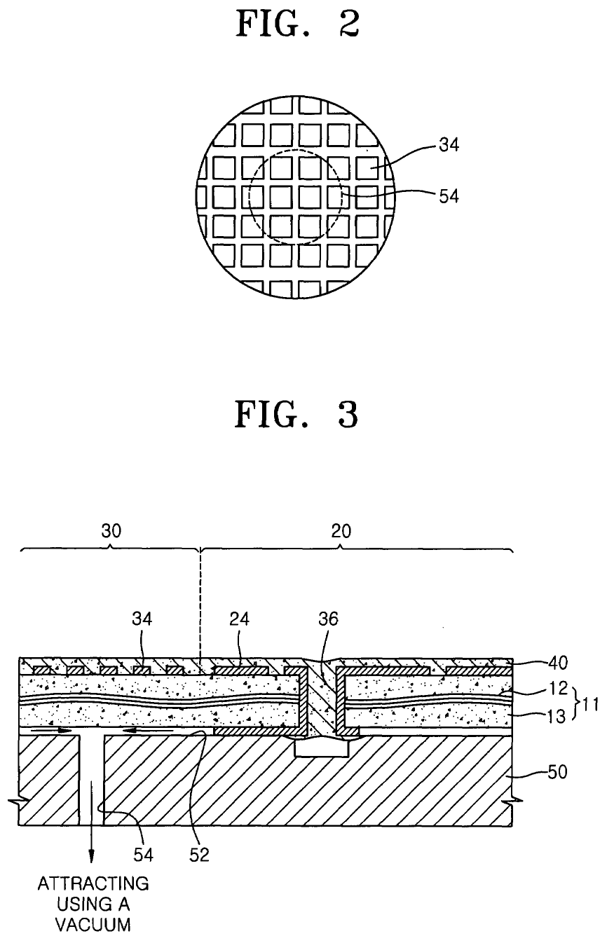

### DETAILED DESCRIPTION OF THE INVENTION

The present invention will now be described more fully with reference to the accompanying drawings in which exemplary embodiments of the invention are shown.

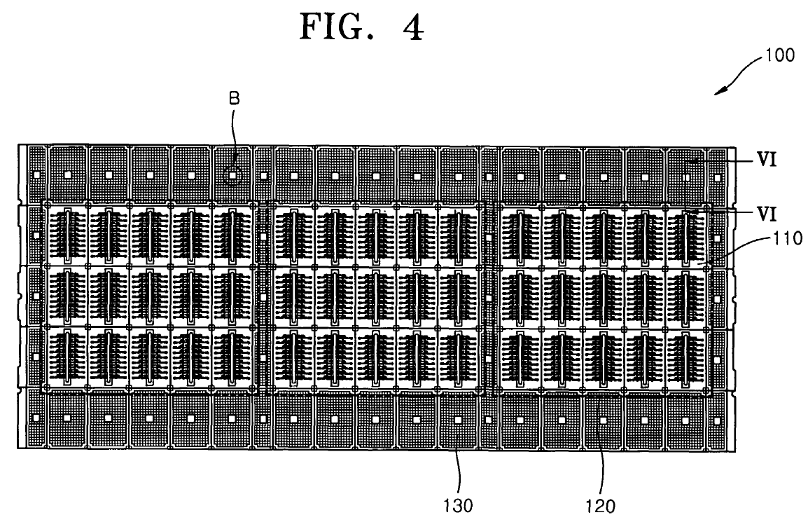

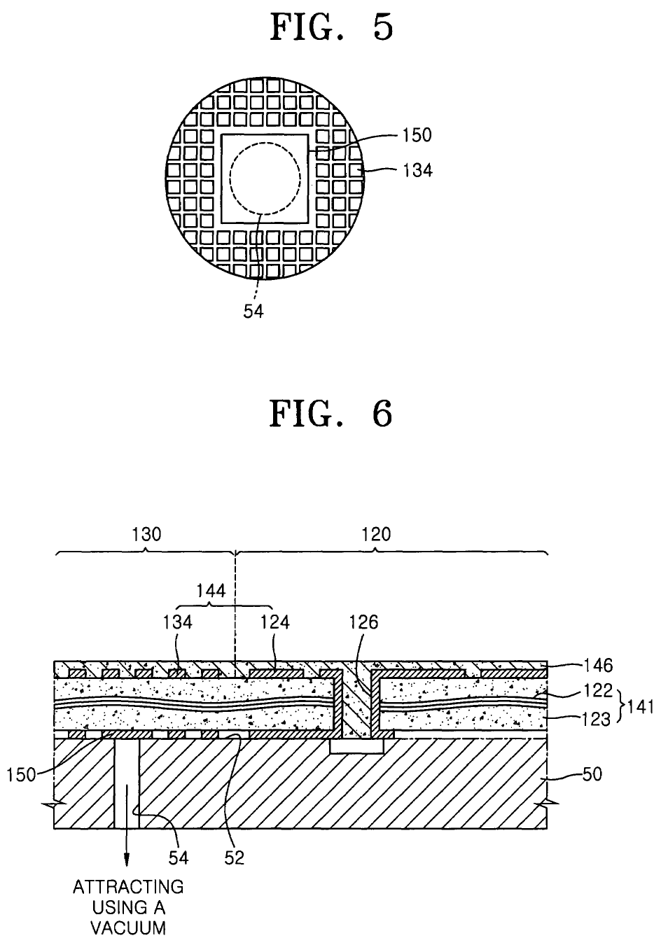

FIG. 4 is a plan view of a board strip 100 according to an embodiment of the present invention. FIG. 5 is an enlarged plan view of a portion indicated by B in FIG. 4, and FIG. 6 is a cross-sectional view taken along line VI-VI of FIG. 4. Referring to FIGS. 4 through 6, the board strip 100 includes a base substrate 141, a circuit layer 144, a protective layer 146, and a vacuuming hole seating unit 150.

As shown in FIGS. 4 and 6, the base substrate 141 is configured with at least one functional portion 120 and at least one non-functional portion 130. The functional portion 120 includes a plurality of unit substrates 110 that are used in combination with semiconductor chips to fabricate a plurality of semiconductor packages. The non-functional portion 130 is normally configured between the functional portions 120 and surrounds the functional portions 120. The base substrate 141 may be formed of BT or FR-4. As shown in FIG. 6, the BT or FR-4 may include a prepreg 122 and a resin material 123 that surrounds the prepreg 122. In this case, the, prepreg 122 denotes a composition of glass fiber and resin. One example prepreg 122 contains 70% or less resin, has an overall thickness of 0.15 mm or less, and has a strength of 25 Gpa or more. These are some of the conditions that may be required for the base substrate 141 including the prepreg 122 and the resin 123 when the base substrate 141 is formed using, for example, the reel-to-reel method. The strength of the prepreg 122 can be controlled by controlling the amounts of the resin 123 that constitutes the prepreg 122 together with the glass fiber.

The circuit layer 144 is formed on at least one surface of the base substrate 141. The circuit layer 144 includes a plurality of circuit patterns 124 that are configured on the functional portion 120 of the base substrate 141 for electrical connection to a semiconductor chip. The circuit layer 144 also includes a plurality of dummy patterns 134 which are configured on the non-functional portion 130 of the base substrate 141. The dummy patterns 134 are configured so that the upper and lower surfaces of the base substrate 141 have a substantially similar thermal expansion rate.

In this case, the circuit pattern 124 and the dummy patterns 134 can be patterned by exposing and developing a conductive film formed of, for example, copper, after the conductive film is formed on the base substrate 141, or by other methods known in the art such as sputtering, vapor deposition, etc. The circuit patterns 124 can be formed on one or both surfaces of the base substrate 141. Circuit patterns 124 when formed on the upper and lower surfaces of the base substrate 141 can be connected to each other through holes such as vias or through holes 126.

The protective layer 146 is formed on the circuit layer 144. The protective layer 146 can be formed of a solder resist or a photo solder resist, and protects the circuit patterns 124 from the environment. In this case, the base substrate 141 is used for a board on chip (BOC) package, and each of the circuit patterns 124 can include an electrode connection unit, a ball seating unit, and a connection unit.

Although not shown, an electrode connection unit of the circuit pattern 124 is connected to an electrode unit of a semiconductor chip, a conductive ball that is electrically connected to an external substrate is seated on the ball seating unit, and the connection unit connects the electrode connection unit to the ball seating unit. In this case, the protective layer 146 can be formed without the electrode connection unit and the ball seating unit. The protective layer 146 can be formed on upper and lower surfaces of the base substrate 141 through the through holes 126.

To form the protective layer 146, particularly, as depicted in FIG. 6, after the base substrate 141 is seated on the vacuum stage 50, a negative pressure is established in the vacuuming holes 54 of the vacuum stage 50 so that the surface of the base substrate 141 (e.g., in the non-functional portion 130 of the base substrate 141) can be attracted to and held on the vacuum stage 50. In this state, the protective layer 146 is coated for example, using a screen printing method.

In the present embodiment, the at least one vacuuming hole seating unit 150 is configured on the base substrate 141 to generally correspond with a configuration of the at least one vacuuming hole 54. As best illustrated in FIG. 6, the vacuuming hole seating unit 150 is substantially the same thickness as the circuit layer 144. However, in other embodiments, the vacuuming hole seating unit 150 may be thicker than the circuit layer 144. Accordingly, because the vacuuming hole seating unit 150 seals the hole 54, the negative pressure in the vacuuming hole 54 does not affect a region surrounding the vacuuming hole seating unit 150 so that the viscous material of the protective layer 146 is attracted to areas of the substrate 141 past the through hole 126. Therefore, the penetration of the protective layer 146 does not occur since the negative pressure does not affect the peripheral areas of the holes.

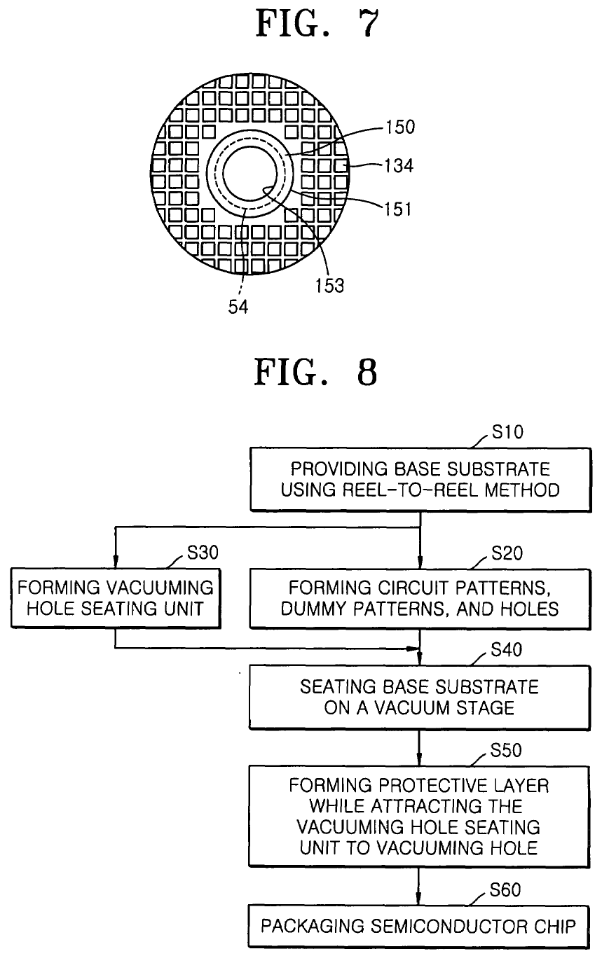

The vacuuming hole seating unit 150 can be formed of the same material as the base substrate 141. That is, the substrate 141 may be made thicker, for example, by adding additional resin 123 in some areas corresponding to the configuration of the at least one vacuuming hole 54. Alternatively, the vacuuming hole seating unit 150 can be formed of the same material as the circuit layer 144 and for example at the substantially same time that the dummy patterns 134 are formed. The vacuuming hole seating unit 150 can have a larger diameter than the vacuuming hole 54. As depicted in FIG. 5, the vacuuming hole seating unit 150 can be formed of the same material as the dummy patterns 134 and can have a square or rectangular shape. Of course, the vacuuming hole seating unit 150 may have other suitable shapes such as circular, oval and other polylinear and curvilinear configurations. As depicted in FIG. 7, the vacuuming hole seating unit 150 may be generally annular or toroidal in shape with an outer rim unit 151 having a diameter greater than that of the vacuuming hole 54 and an inner rim unit 153 that may have a diameter smaller than that of the vacuuming hole 54.

According to the present embodiment, the generation of voids in the protective layer 146 disposed in the through holes 126 and the penetration of the unhardened protective layer 146 into a region surrounding the through holes 126 between the base substrate 141 and the vacuum stage 50 can be prevented by sealing the at least one vacuuming hole 54 with the at least one vacuuming hole seating unit 150. Likewise, the flatness of the base substrate 141 can be increased.

FIG. 8 is a flowchart of an example method of manufacturing a semiconductor package according to an aspect of the present invention. Referring to FIG. 8, the method of manufacturing a semiconductor package includes: providing a base substrate, for example, using a reel-to-reel process (S10); forming circuit patterns on and holes in a functional portion of the base substrate, and forming dummy patterns on a non-functional portion of the base substrate (S20); forming vacuuming hole seating units on the non-functional portion (S30); seating the base substrate on a vacuum stage (S40) so that the vacuuming hole seating units substantially seal vacuuming holes of the vacuum stage; forming a protective layer on the base substrate while the vacuuming hole seating unit of the base substrate is fixed on the vacuuming hole by vacuuming the vacuuming hole (S50); and packaging a semiconductor chip on the base substrate (S60).

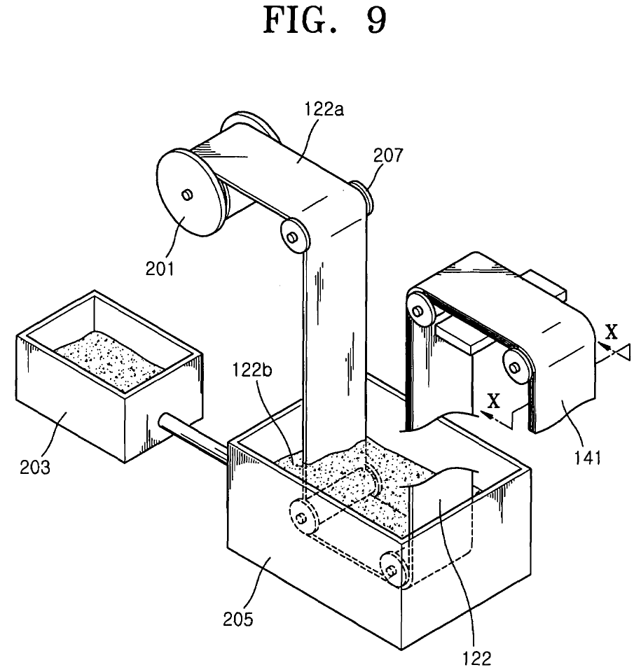

Steps of the example method shown in FIG. 8 will now be described in detail with reference to FIGS. 9 through 12. Referring to FIGS. 9 and 10, a base substrate 141 is provided. The base substrate 141 can include at least one layer of prepreg 122 formed of a composition of glass fiber and resin, and a resin material 123 formed around the prepreg 122. In the present embodiment, the prepreg 122 may be supplied using a reel-to-reel method.

In an example reel-to-reel method, a glass fiber material 122a wound around a rolling supply device 201 is supplied to a resin tank 205. The resin tank 205 contains a liquid state resin 122b that is supplied from a resin storage 203. The glass fiber material 122a is fed into the resin tank 205 and immersed into the liquid state resin 122b. After immersion in the resin 122b, the glass fiber material 122a and resin 122b thereon is cured, for example, by heating in an oven, and thus, prepreg 122 is manufactured. One or more rollers 207 may be used to guide the prepreg 122.

One example prepreg 122 contains 70% or less resin, has an overall thickness of 0.15 mm or less, and has a strength of 25 Gpa or more. When these conditions are satisfied, the base substrate 141 can be supplied by the reel-to-reel method and also, can maintain a predetermined strength when the base substrate 141 is bent in a subsequent process. The strength of the prepreg 122 can be controlled by controlling the amounts of the resin material 123 that constitutes the prepreg 122 together with the glass fiber 122a.

The base substrate 141 can be formed of FR-4 or BT. In some instances, use of FR-4 is advantageous due to its hygroscopic, retardant, adhesive, and high conductivity material properties. A thermal coefficient of the base substrate 141 can be controlled by controlling the amounts of filler added to the resin 122b.

Afterward, as depicted in FIG. 11, a circuit pattern 124 is formed on at least one surface of the functional portion 120 of the base substrate 141, and also, the dummy patterns 134 are formed on at least one surface of the non-functional portion 130 of the base substrate 141. For example, in an embodiment of the present invention, a conductive film is formed on at least one surface of the base substrate 141 by dipping, sputtering, vapor deposition etc. Next, after coating a photosensitive film on an upper surface of the conductive film, the circuit pattern 124 and the dummy patterns 134 can be formed by exposing and developing (e.g., etching). An operation of forming a plurality of holes 126 in the base substrate 141 may be performed before or substantially simultaneously with formation of the patterns 124, 134. The holes 126 include vias or through holes that electrically connect the circuit patterns 124 formed on the upper and lower surfaces of the base substrate 141.

The present invention further includes an operation of forming vacuuming hole seating units 150, for example, in the non-functional portion 130 of the base substrate 141. In some instances, the vacuuming hole seating units 150 are formed of the same material as the dummy patterns 134, and may be formed in the same process as the dummy patterns 134. The vacuuming hole seating units 150 are configured to generally correspond with a configuration of vacuuming holes 54 and, furthermore, may have a greater diameter than the vacuuming hole 54 so that the negative pressure of the vacuuming hole 54 cannot affect the region surrounding the vacuuming hole 54. The vacuuming hole seating units 150 may have any suitable configuration to seal the vacuuming holes 54, for example, the vacuuming hole seating units 150 may have an annular shape with an outer rim unit 151 having a greater diameter than the vacuuming hole 54 and an inner rim unit 153 having a smaller diameter than the vacuuming hole 54.

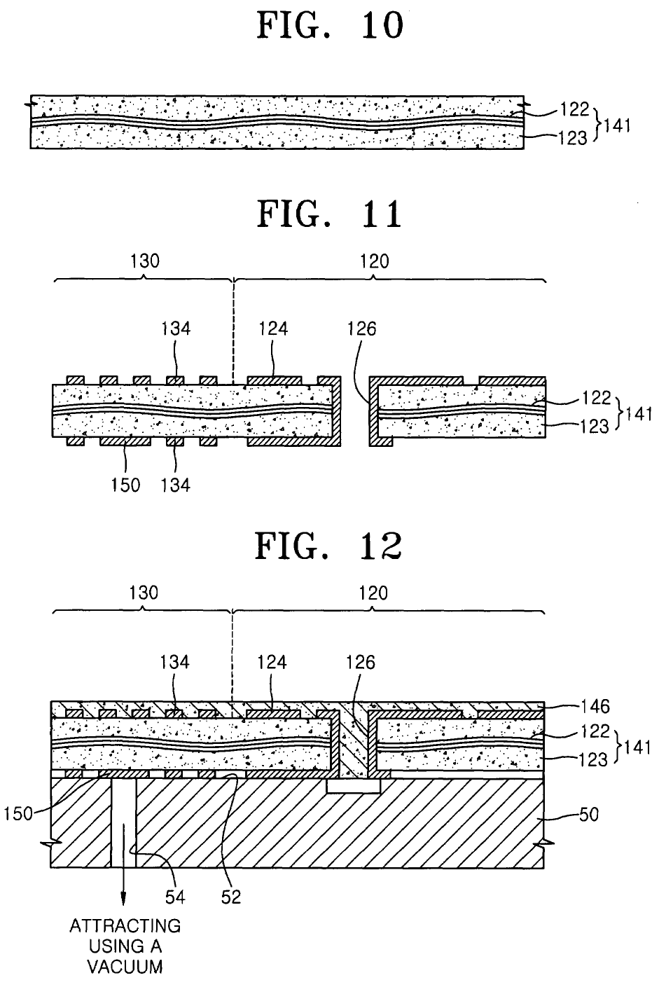

Afterward, as depicted in FIG. 12, to form the protective layer 146 on the circuit pattern 124, operations for seating the base substrate 141 on the vacuum stage 50 and for fixing the base substrate 141 by establishing a negative pressure in the vacuuming hole 54 included in the vacuum stage 50 to attract the vacuuming hole seating unit 150, are performed. The vacuuming hole seating unit 150 has a thickness that is substantially similar to (or in some instances, greater than) a thickness of the patterns 124,134 that are proximate thereto. Therefore, when the vacuuming hole 54 contacts the vacuuming hole seating unit 150, the vacuuming hole 54 is sealed so that negative pressure does not affect the region surrounding the vacuuming hole 54. In this state, the protective layer 146 is formed on the base substrate 141. Therefore, the protective layer 146 is coated in a state in which the base substrate 141 is completely flat, and the protective layer 146 fills the through holes 126.

In this case, the through holes 126 are not affected by the negative pressure of the vacuuming hole 54. Therefore, the protective layer 146 substantially completely fills the through holes 126, and does not penetrate regions surrounding the through holes 126 between the base substrate 141 and the vacuum stage 50.

Afterward, although not shown, a semiconductor chip and the base substrate 141 are packaged. In this case, the semiconductor chip and the base substrate 141 can be board on chip (BOC) packaged. That is, the semiconductor chip is seated upside down on an upper part of the base substrate 141, which has an electrode connection unit and a ball seating unit on a lower surface thereof. In this case, an electrode unit of the semiconductor chip is disposed in an inner space of a window slit. Next, the electrode unit of the semiconductor chip and the electrode connection unit of the base substrate 141 are wire bonded. Afterward, the resultant product including the wire bonding portion is molded or encapsulated using a molding material.

Afterward, the manufacture of semiconductor packages is completed by separating each of the printed circuit substrates, for example by cutting.

According to the present invention, since a protective layer can be formed in a state in which the base substrate is vacuumed through a vacuuming hole that contacts a flat vacuuming hole seating unit, the penetration of the protective layer into regions surrounding the through holes between the base substrate and the vacuum stage and thus, the of generation of voids in the protective layer can be prevented, and printed circuit substrates can have high flatness. As a result, the reliability of the semiconductor package is increased.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A board strip comprising:
a base substrate including at least one functional portion in which at least one semiconductor chip is packaged, at least one non-functional portion proximate the at least one functional portion, and at least one hole;
a circuit layer including a circuit pattern formed on at least one surface of the at least one functional portion, and a dummy pattern formed on at least one surface of the at least one non-functional portion;
a protective layer formed on the circuit layer; and
at least one vacuuming hole seating unit that is formed on a part of the at least one nonfunctional portion, the at least one vacuuming hole seating unit being configured to seal a vacuuming hole of a vacuum stage.

2. The board strip of claim 1, wherein the at least one vacuuming hole seating unit is formed of the same material as the dummy pattern.

3. The board strip of claim 2, wherein the at least one vacuuming hole seating unit has a greater area than the vacuuming hole.

4. The board strip of claim 2, wherein the at least one vacuuming hole seating unit is generally annular in shape and includes an external rim unit having a first perimeter that is greater than a perimeter of the vacuuming hole, and an inner rim unit having a second perimeter that is smaller than the perimeter of the vacuuming hole.

5. The board strip of claim 1, wherein the base substrate is selected from the group consisting of FR-4 and bismaleimide triazine.

6. The board strip of claim 1 wherein the at least one functional portion is substantially surrounded by the at least one non-functional portion.

7. The board strip of claim 1 wherein the at least one functional portion is configured in a central portion of the board strip.

8. A board strip including a base substrate with at least one functional portion having a circuit pattern on which at least one semiconductor chip is packaged, at least one non-functional portion having a dummy pattern and a protective layer formed on the circuit pattern and the dummy pattern;
wherein the improvement comprises at least one vacuuming hole seating unit that is formed on a part of the non-functional portion, the at least one vacuuming hole seating unit being configured to seal a vacuuming hole of a vacuum stage.

9. The board strip of claim 8, wherein the at least one vacuuming hole seating unit is formed of the same material as the dummy pattern.

10. The board strip of claim 8, wherein the at least one vacuuming hole seating unit has a greater area than the vacuuming hole.

11. The board strip of claim 8, wherein the at least one vacuuming hole seating unit is generally annular in shape and includes an external rim unit having a first perimeter that is greater than a perimeter of the vacuuming hole, and an inner rim unit having a second perimeter that is smaller than the perimeter of the vacuuming hole.

12. A method of manufacturing a semiconductor package comprising:
providing a base substrate;
forming circuit patterns on functional portions of the base substrate and dummy patterns on non-functional portions of the base substrate;
forming at least one hole through the base substrate;
forming at least one vacuuming hole seating unit on the non-functional portions of the base substrate, the at least one vacuuming hole seating unit being configured to correspond with at least one vacuuming hole of a vacuum stage;
seating the base substrate on the vacuum stage so that the at least one vacuuming hole seating unit seals the at least one vacuuming hole;
establishing a negative pressure in the at least one vacuuming hole to hold the base substrate on the vacuum stage;
forming a protective layer on the base substrate; and
packaging a semiconductor chip on the base substrate.

13. The method of claim 12, wherein the providing step comprises supplying the base substrate from a roll or reel.

14. The method of claim 12, wherein the step of forming at least one vacuuming hole seating unit is performed substantially simultaneously as the step of forming dummy patterns.
